(19) United States
(12) Patent Application Publication
(10) Pub. No.: US 2005/0087793 A1
(43) Pub. Date: Apr. 28, 2005

(54) Embedded non-volatile memory and a method for fabricating the same

(75) Inventors: Sung Mun Jung, Kyungki-do (KR); Dong Oog Kim, Seoul (KR)

Correspondence Address: Finnegan, Henderson, Farabow,;Garrett & Dunner, L.L.P., 1300 I Street, N.W., Washington, DC, 20005-3315, US

(73) Assignee: DONGBU ELECTRONICS CO., LTD.

(21) Appl. No.: 10/969,995

(22) Filed: Oct. 22, 2004

(30) Foreign Application Priority Data
Oct. 23, 2003 (KR) 10-2003-0074444

(51) Int. Cl. H01L 21/336; H01L 29/792; H01L 29/76

(52) U.S. Cl. 257/314; 438/257; 438/261; 257/324

(57) ABSTRACT

A low density and cost effective embedded non-volatile memory cell includes a semiconductor substrate of a first conductivity type and having device isolation regions and active regions defined therein; a first well of a second conductivity type in the semiconductor substrate; a plurality of second wells of the first conductivity type inside the first well, the second wells being formed in parallel with a bit line and surrounded by the device isolation regions and the first well; a plurality of ONO structures formed over corresponding ones of the second wells, each ONO structure including a first oxide film, a nitride film, and a second oxide film; and a plurality of gates formed on corresponding ones of the ONO structures and formed in parallel with a word line.

### RELATED ART

This application is based on and claims benefit of Priority to Korean Patent Application No. 10-2003-0074444 filed on Oct. 23, 2003, the entire contents of which are incorporated herein by reference.

### BACKGROUND

(a) Technical Field

The present invention relates to a method for fabricating a semiconductor device and, in particular, to a method for fabricating a low density and cost effective embedded non-volatile memory.

(b) Description of the Related Art

An embedded non-volatile (nv) memory is formed as a single chip integrated with a non-volatile memory device and a logic circuit for driving the device. Such embedded non-volatile memory is manufactured using a basic logic technology and non-volatile memory technology. There are various types of embedded non-volatile memories used for various purposes. The embedded non-volatile memory family includes single poly EEPROM having a single polycrystalline silicon layer, stack gate type memory (ETOX) formed by vertically stacking two polycrystalline silicon layers, dual poly EEPROM, and split gate type memory. The cell sizes of the dual poly EEPROM and split gate type memory are between that of the single poly EEPROM and the stack gate memory.

Typically, a stack gate type memory has a minimum cell size and high circuitry complexity and is appropriate for high density, high performance devices. Compared to a stack gate type memory, EEPROM is generally more suitable for low density purposes. However, the fabrication of a single poly EEPROM requires about two additional mask processing phases in a logic process. The cell size of a single poly EEPROM is about 200 times larger than that of the stack gate type memory. On the other hand, the fabrication process of a dual poly EEPROM or a split gate type memory is generally complex.

Accordingly, it is required to develop a novel structure of low density embedded non-volatile memory that can be fabricated in low manufacturing costs.

### SUMMARY

Consistent with the present invention, there is provided an embedded non-volatile memory that includes a semiconductor substrate of a first conductivity type and having device isolation regions and active regions provided therein, a first well of a second conductivity type in the semiconductor substrate, a plurality of second wells of the first conductivity type inside the first well, the plurality of second wells being formed in parallel with a bit line and surrounded by the device isolation regions and the first well, a plurality of ONO structures formed over corresponding ones of the second wells, each ONO structure including a first oxide film, a nitride film, and a second oxide film, and a plurality of gates formed on corresponding ones of the ONO structures, and formed in parallel with a word line.

Consistent with the present invention, there is also provided a method for fabricating an embedded non-volatile memory that includes providing a semiconductor substrate having a first conductivity type, forming device isolation regions in the semiconductor substrate, forming a first well having a second conductivity inside the semiconductor substrate, forming a plurality of second wells having the first conductivity type inside the first well, wherein the second wells are formed in parallel with a bit line and are surrounded by the device isolation regions and the first well, forming a plurality of ONO structures by sequentially forming a first oxide film, a nitride film, and a second oxide film over the second wells, and forming a plurality of gates on the ONO structures, wherein the plurality of gates are formed in parallel with a word line.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawing, which is incorporated in and constitutes a part of this specification, illustrates embodiments of the invention and, together with the description, serves to explain the objects, advantages, and principles of the invention.

FIG. 1 is a plan view illustrating an embedded non-volatile memory consistent with a preferred embodiment of the present invention;

FIG. 2A is a cross sectional view of the embedded non-volatile memory of FIG. 1 taken along a bit line at A-A′; and

FIG. 2B is a cross sectional view of the embedded non-volatile memory of FIG. 1 taken along a word line at B-B′.

### DETAILED DESCRIPTION OF THE EMBODIMENTS

Embodiments of the present invention will be described hereinafter with reference to the accompanying drawings.

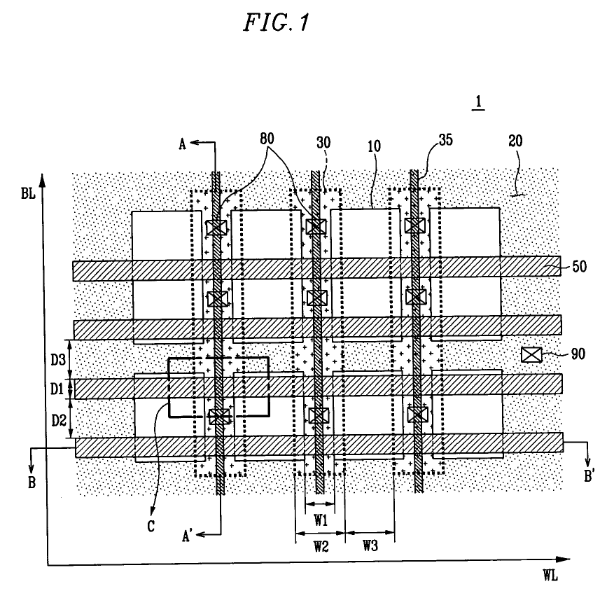

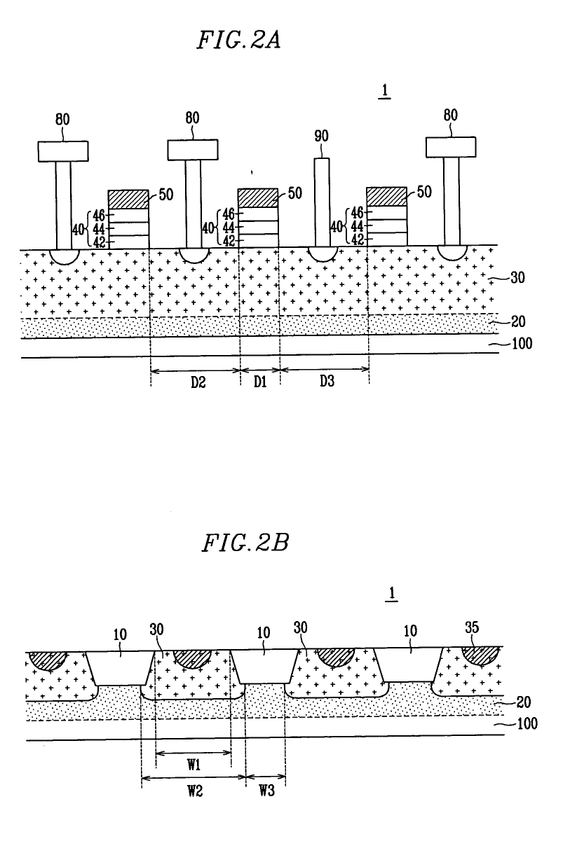

FIG. 1 is a plan view illustrating an embedded non-volatile memory 1 consistent with an embodiment of the present invention, FIG. 2a is a cross sectional view of embedded non-volatile memory 1 taken along a bit line A-A′ in FIG. 1 and FIG. 2b is a cross sectional view of embedded non-volatile memory 1 taken along a word line B-B′ in FIG. 1.

As shown in FIGS. 2A and 2B, a semiconductor substrate 100 includes a plurality of device isolation regions 10 formed therein as device isolation regions to define a plurality of active regions in which devices are formed.

Device isolation regions 10 may comprise shallow trench isolations (STIs), local oxidation of silicon (LOCOS), or deep trench isolations (DTIs). In an aspect, STIs are used as device isolation regions 10 because STI is superior to LOCOS in view of the high integrity characteristic and to DTI in view of simplicity of fabrication.

A first well 20 in which devices are to be formed is formed in the entire surface of semiconductor substrate 100 having the device isolation regions and the active regions defined therein. First well 20 has a different conductivity type than semiconductor substrate 100. For example, if semiconductor substrate 100 is n-type, first well 20 is formed to be p-type.

The first well 20 includes a plurality of second wells 30 having a conductivity type different than that of first well 20 are formed in parallel with a bit line. For example, if first well 20 is n-type, second wells 30 are p-type. Here, each second well 30 is surrounded by device isolation regions 10 and first well 20, and is isolated from other second wells 30.

Each second well 30 includes a metal bit line 35 formed therein and the metal bit lines in second wells 30 are also isolated from each other because second wells 30 are surrounded by device isolation regions 10 and first well 20. Accordingly, it is possible to individually control each bit line.

Typically, first and second wells 20 and 30 are formed by ion implantations. For example, when the semiconductor substrate 100 is a p-type silicon wafer, first wells 20 are n-type and may be formed by diffusing ions of element belonging to Group V-A of the Periodic table into semiconductor substrate 100. Accordingly, second wells 30 are p-type and may be formed by diffusing ions of element belonging to Group III-A of the Periodic table into first wells 20, each second well 30 being isolated from neighboring second wells 30.

Embedded non-volatile memory 1 also includes a plurality of oxide-nitride-oxide (ONO) structures 40 (FIG. 2A) and a plurality of gates 50, each ONO structure 40 and each gate 50 being over one of second wells 30. Each ONO structure 40 includes a first oxide film 42, a nitride film 44, and a second oxide film 46. Each gate 50 is formed on a corresponding ONO structure 40 and is in parallel with a word line. ONO structures 40, gates 50, and second wells 30 including the metal bit lines therein collectively constitute embedded non-volatile memory 1, which is a silicon ONO silicon (SONOS) flash memory device. Embedded non-volatile memory 1 includes a plurality of memory cells, wherein each memory cell is defined at a cross between an ONO layer 40, a gate 50, and a second well 30.

In one aspect, the first oxide film of ONO structure 40 has a thickness in the range of 10-50 Å, the nitride film has a thickness in the range of 50-160 Å, and the second oxide film has a thickness in the range of 10-80 Å.

Embedded non-volatile memory 1 also include a plurality of drain contacts 80 arranged in the bit line direction and a plurality of common source contacts 90 arranged in the word line direction, wherein each drain contact 80 provides a contact to a drain of each memory cell and each common source contact 90 provides a contact to a source shared by more than one memory cells.

Also as shown in FIG. 2A, each drain contact 80 contacts a corresponding drain region of a memory cell at a well pick-up.

A method for fabricating embedded non-volatile memory 1 consistent with the present invention will be described hereinafter in detail.

First, active regions in which devices are to be formed are defined by forming device isolation regions 10 in a semiconductor substrate 100 having a first conductivity type. The first conductivity type may be n-type or p-type.

Device isolation regions 10 may be formed using technologies such as shallow trench isolations (STIs), or local oxidation of silicon (LOCOS), or deep trench isolations (DTI).

Next, first well 20 is formed by implanting impurity ions having a second conductivity type different from the first conductivity type, into the entire surface of semiconductor substrate 100. For example, when semiconductor substrate 100 is p-type, first well 20 is n-type and may be formed by injecting ions of an element belonging to Group V-A of the Periodic table such as phosphor (P).

Next, a plurality of second wells 30 having the first conductivity type are formed by injecting the impurity ions having the first conductivity type into first well 20 in semiconductor substrate 100. The impurity ions having the first conductivity type are prevented from being injected into device isolation regions 10 by masking device isolation regions 10 with a photoresist mask. In one aspect, semiconductor substrate 10 comprises a p-type silicon wafer, and second wells 30 are p-type and can be formed by injecting ions of an element belonging to Group III-A of the Periodic table such as boron (B).

In one aspect, second wells 30 are formed in parallel with a bit line and surrounded by device isolation regions 10 and first well 20. Therefore, second wells 30 are isolated from each other.

Next, ONO structures 40 are formed over second wells 30 by sequentially depositing a first oxide film, a nitride film, and a second oxide film on the entire surface of the semiconductor substrate 100 and then selectively etching the first oxide film, the nitride film, and the second oxide film, such that each ONO structure 40 includes a remaining portion of the first oxide film, the nitride film, and the second oxide film over the second well. In one aspect, the first oxide film is formed at a thickness in the range of 10-50 Å by a thermal oxidation process, the nitride film is formed at a thickness in the range of 50-160 Å by a chemical vapor deposition (CVD) process, and the second oxide film is formed at a thickness in the range of 10-80 Å also by a CVD process.

Next, gates 50 are formed in a direction parallel with the word line, each gate 50 being formed on a corresponding ONO structure 40.

Sequentially, drain contacts 80 are formed on second wells 30 in the bit line direction and common source contacts 90 are formed in the word line direction.

Assuming that a width of each gate 50 formed in the bit line (BL) is D1, a distance between the gates 50 is D2, a distance between gates 50 sharing a common source is D3, a distance between device isolation regions 10 in the word line direction is W1, a width of second wells 30 in word line direction is W2, and a distance between second wells 30 is W3, the size of each memory cell of embedded non-volatile memory 1 is approximately (D1+D2/2+D3/2)×(W2+W3), as indicated by a dashed rectangle c in FIG. 1.

In one aspect, 0.18 μm linewidth techniques are employed such that D1, D2, D3, W1, W2, and W3 are 0.24 μm, 0.54 μm, 0.6 μm, 0.3 μm, 0.6 μm, and 2 μm, respectively. Thus, the size of a memory cell of embedded no-volatile memory 1 is 0.81×2.6=2.106 μm².

In embedded non-volatile memory 1 formed using a method consistent with an embodiment of the present invention as discussed above, each memory cell defined at a cross point of one of gates 50 and one of second wells 30 may be programmed, erased, or read using an F-N tunneling mechanism. Memory 1 also includes pads (not shown) for receiving signals through which the signals may be applied to each memory cell. For example, during the programming operation of a memory cell, a voltage of about +6V is applied to a corresponding one of gates 50 and a voltage of about −6V is applied to a corresponding one of second wells 30 such that electrons tunnel into the nitride film of the corresponding one of ONO structures 40 and are trapped therein. On the other hand, during the erasing operation of a memory cell, a voltage of about −6V is applied to a corresponding one of gates 50 and a voltage of +6V is applied to a corresponding one of second wells 30 such that the electrons and holes recombine in the nitride film of the corresponding one of ONO structures 40.

When electrons are trapped in the nitride film of ONO structure 40 of a memory cell, a threshold voltage of the memory cell increases such that a drain current of the memory cell becomes 0 in a reading operation. On the other hand, if electrons are recombined with holes in the nitride film of ONO structure 40 of a memory cell, a drain current of the memory cell may be sensed in a reading operation. Accordingly, the drain currents may be sensed to reflect a status of the corresponding memory cell.

Suitable voltages to be applied to gate 50 and second well 30 of a memory cell are as follows. To program a memory cell and therefore increase the threshold voltage of the memory cell, a voltage in the range of +4˜+10V may be applied to gate 50 of the memory cell and a voltage in the range of −4˜10V may be applied to second well 30 of the memory cell. On the other hand, to erase a memory cell and therefore decrease the threshold voltage of the memory cell, a voltage in the range of −4˜−10V may be applied to gate 50 of the memory cell and a voltage in the range of +4˜+10V may be applied to second well 30 of the memory cell.

As described above, the memory device consistent with the present invention is an SONOS flash memory device and utilizes a triple well structure and thus, the programming and erasing thereof may be carried out on a bit-by-bit basis.

Table 1 shows chip sizes of a memory device consistent with the present invention as compared to various types of conventional embedded non-volatile memories, and Table 2 shows the number of mask processes in addition to those required by a logic circuit for a memory device consistent with the present invention as compared to various types of conventional embedded non-volatile memories.

TABLE 1

| | | Cell (Core) Size | | | Chip Size | | | | |
|---|---|---|---|---|---|---|---|---|---|
| | | predic- | Core | Array | according to the Cell density | | | | |
| | | tion | Size | size | 1K | 10K | 100K | 1 M | 10 M |
| Conventional | Single Poly | 100 | 0.72 | 100.72 | 1.47 | 2.38 | 11.44 | 102 | 1008 |
| | EEPROM | | | | | | | | |
| | Dual Poly | 11.23 | 0.72 | 11.95 | 1.38 | 1.49 | 2.57 | 13.3 | 120 |
| | EEPROM | | | | | | | | |
| | Stack Gate | 0.28 | 0.72 | 1 | 2.87 | 2.88 | 2.97 | 3.87 | 12.87 |
| | (ETOX) | | | | | | | | |
| | Split Gate | 0.6 | 0.72 | 1.32 | 2.12 | 2.13 | 2.25 | 3.44 | 15.32 |
| Present | Embodiment | 2.106 | 0.72 | 2.88 | 1.37 | 1.40 | 1.66 | 4.25 | 30.17 |
| Invention | | | | | | | | | |

TABLE 2

| | | Number of Mask Processes in Addition | | |
|---|---|---|---|---|
| | | to Those Required by a Logic Circuit | | |
| | | Light Source: | Light Source: | |
| | | DUV | i-line | Total |
| Conventional | Single Poly | 0 | 2 | 2 |
| | EEPROM | | | |
| | Dual Poly | 2 | 8 | 10 |
| | EEPROM | | | |
| | Stack Gate | 3 | 7 | 10 |
| | (ETOX) | | | |
| | Split Gate | 3 | 7 | 10 |
| Present | Embodiment | 0 | 4 | 4 |
| Invention | | | | |

As shown in Table 1 and Table 2, a single poly EEPROM has a chip size that is too large when the cell density is over 100K. A stack gate memory device requires too many additional processes.

In contrast, the present invention provides for a memory device that requires less additional processes than a conventional stack gate memory device and that has a chip size smaller than most conventional embedded non-volatile memory devices. Therefore, a manufacturing cost of a memory device consistent with the present invention is reduced.

As described above, the present invention provides for a single poly SONOS flash device having a triple-well structure, which may be programmed and erased on a bit-by-bit basis. Therefore, it is possible to implement a low density and cost effective embedded volatile memory cell.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. An embedded non-volatile memory comprising:
a semiconductor substrate of a first conductivity type and having device isolation regions and active regions provided therein;
a first well of a second conductivity type in the semiconductor substrate;
a plurality of second wells of the first conductivity type inside the first well, the plurality of second wells being formed in parallel with a bit line and surrounded by the device isolation regions and the first well;
a plurality of ONO structures formed over corresponding ones of the second wells, each ONO structure including a first oxide film, a nitride film, and a second oxide film; and
a plurality of gates formed on corresponding ones of the ONO structures, and formed in parallel with a word line.

2. The embedded non-volatile memory of claim 1, further comprising metal bit lines inside the second wells, wherein the metal bit lines are isolated from each other by the device isolation regions and the first well.

3. The embedded non-volatile memory of claim 1, wherein the first oxide film has a thickness in a range of 10-50 Å.

4. The embedded non-volatile memory of claim 1, wherein the second oxide film of has a thickness in a range of 10-80 Å.

5. The embedded non-volatile memory of claim 1, wherein the nitride film of each of the ONO structures has a thickness in a range of 50-160 Å.

6. The embedded non-volatile memory of claim 1, wherein the semiconductor substrate comprises a p-type silicon wafer, the first well comprises a n-well formed by injecting ions of an element belonging to Group V-A of the Periodic table, and the second well comprises a p-well formed by injecting ions of an element belonging to Group III-A of the Periodic table.

7. The embedded non-volatile memory of claim 1, wherein
the plurality of gates, the plurality of ONO structures, and the plurality of second wells define a plurality of memory cells, each memory cell corresponding to one of the gates, one of the ONO structures, and one of the second wells;
the memory includes pads for receiving signals so that during a programming operation of a memory cell, the gate of the respective memory cell receives a voltage in the range of +4˜+10V and the second well of the respective memory cell receives a voltage in the range of −4˜−10V, and
during an erasing operation of a memory cell, the gate of the respective memory cell receives a voltage in the range of −4˜−10V and the second well of the respective memory cell receives a voltage in the range of +4˜+10V.

8. A method for fabricating an embedded non-volatile memory comprising
providing a semiconductor substrate having a first conductivity type;
forming device isolation regions in the semiconductor substrate;
forming a first well having a second conductivity inside the semiconductor substrate;
forming a plurality of second wells having the first conductivity type inside the first well, wherein the second wells are formed in parallel with a bit line and are surrounded by the device isolation regions and the first well;
forming a plurality of ONO structures by sequentially forming a first oxide film, a nitride film, and a second oxide film over the second wells; and
forming a plurality of gates on the ONO structures, wherein the plurality of gates are formed in parallel with a word line.

9. The method of claim 8, wherein forming the second well comprises injecting impurity ions into the semiconductor substrate after covering the device isolation regions using a photoresist mask.

10. The method of claim 8, wherein forming the first well comprises injecting impurity ions into an entire surface of the semiconductor substrate.

11. The method of claim 8, wherein
the semiconductor substrate comprises a p-type silicon wafer, and
forming the first well comprises injecting impurity ions of an element belonging to Group V-A of the Periodic table.

12. The method of claim 8, wherein
the semiconductor substrate comprises a p-type silicon wafer, and
forming the second well comprises injecting impurity ions of an element belonging to Group III-A of the Periodic table.

13. The method of claim 8, wherein forming the first oxide film comprises forming the first oxide film to a thickness in a range of 10-50 Å by a thermal oxidation process.

14. The method of claim 8, wherein forming the nitride film comprises forming the nitride film to a thickness in a range of 50-160 Å by a chemical vapor deposition (CVD) process.

15. The method of claim 13, wherein forming the nitride film comprises forming the nitride film to a thickness in a range of 50-160 Å by a chemical vapor deposition (CVD) process.

16. The method of claim 8, wherein forming the second oxide film comprises forming the second oxide film to a thickness in a range of 10-80 Å by a chemical vapor deposition (CVD) process.

17. The method of claim 15, wherein forming the second oxide film comprises forming the second oxide film to a thickness in a range of 10-80 Å by the CVD process.

18. The method of claim 8, wherein forming the ONO structures includes sequentially depositing the first oxide film, the nitride film, and the second oxide film on the entire surface of the semiconductor substrate and then selectively etching the first oxide film, the nitride film, and the second oxide film, such that each ONO structure 40 has a desired width and includes a remaining portion of the first oxide film, the nitride film, and the second oxide film over the second well.

19. The method of claim 17, wherein forming the ONO structures includes sequentially depositing the first oxide film, the nitride film, and the second oxide film on the entire surface of the semiconductor substrate and then selectively etching the first oxide film, the nitride film, and the second oxide film, such that each ONO structure 40 has a desired width and includes a remaining portion of the first oxide film, the nitride film, and the second oxide film over the second well.
